(19) United States
(12) Patent Application Publication
(10) Pub. No.: US 2008/0057195 A1
(43) Pub. Date: Mar. 6, 2008

(54) Non-line of sight coating technique

(75) Inventor: Kevin W. Schlichting, Storrs, CT (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: United Technologies Corporation, Hartford, CT (US)

(21) Appl. No.: 11/513,890

(22) Filed: Aug. 31, 2006

(51) Int. Cl. C23C 16/00

(52) U.S. Cl. 427/248.1; 118/715

(57) ABSTRACT

An apparatus for non-line of sight coating of a part includes a housing, a vapor source, at least one nozzle, and a vacuum pumping system. The vapor source produces a vapor cloud into the housing and toward the part. The nozzle provides a gas flow to interact with the vapor cloud. The vacuum pumping system maintains a pressure within the housing.

### BACKGROUND OF THE INVENTION

Due to the high temperature environment surrounding gas turbine engines, ceramic thermal barrier coatings (TBCs) are commonly applied to combustors and high turbine stationary and rotating parts to extend the life of the parts. TBCs typically consist of a metallic bond coat and a ceramic top coat applied to a nickel or cobalt based alloy. The coatings are applied at thicknesses of between approximately 125 microns and 1270 microns and can provide up to a 150 degree Celsius temperature reduction to the base metal. Thus, the coating provides the part with increased durability, allows for higher operating temperatures, and results in improved turbine efficiency.

Currently, one method of applying TBCs to a part is by an electron beam physical vapor deposition (EB-PVD) process. While effective, the EB-PVD process is a line of sight process. In a standard EB-PVD process, a vapor cloud is formed from a molten pool and drifts toward the part, where it deposits on the surface of the part. The particles in the vapor cloud have a small amount of particle-to-particle interaction, resulting in little randomization of the vapor cloud. Due to the lack of randomization, the particles are typically only deposited on the surfaces of the part that lie directly in the path emanating from the molten pool. Any region of the part that does not lie directly in the path of the vapor cloud is not coated without physically rotating the part. Thus, it would be desirable to have a system that is capable of applying a coating onto both line of sight regions as well as non-line of sight regions of a part.

### BRIEF SUMMARY OF THE INVENTION

An apparatus for non-line of sight coating of a part includes a housing, a vapor source, at least one nozzle, and a vacuum pumping system. The vapor source produces a vapor cloud into the housing and toward the part. The nozzle provides a gas flow to interact with the vapor cloud. The vacuum pumping system maintains a pressure within the housing.

### BRIEF DESCRIPTION OF THE DRAWINGS

FIG. 1 is a side view of a non-line of sight coating system.

FIG. 2 is a block diagram of a method of coating non-line of sight regions of a part.

### DETAILED DESCRIPTION

The non-line of sight coating system provides improved resistance to oxidation and thermal mechanical fatigue by comprehensively applying a thermal barrier coating to a part. The part is positioned within a housing that is maintained at a low pressure by a vacuum pumping system. A shaft positions the part between a vapor source and an inert gas source. The vapor source introduces a vapor cloud into the housing toward the line of sight regions of the part. The inert gas is introduced into the housing toward the non-line of sight regions of the part by a plurality of nozzles attached to a shield. As the vapor cloud and the inert gas interact, particle-to-particle collisions cause randomization of the vapor cloud and push the vapor cloud back toward the non-line of sight regions of the part. Thus, the coating system coats the non-line of sight regions of the part, accelerates coating of the line of sight regions of the part, and improves the microstructure of the areas of the part that are not in direct alignment with the vapor source.

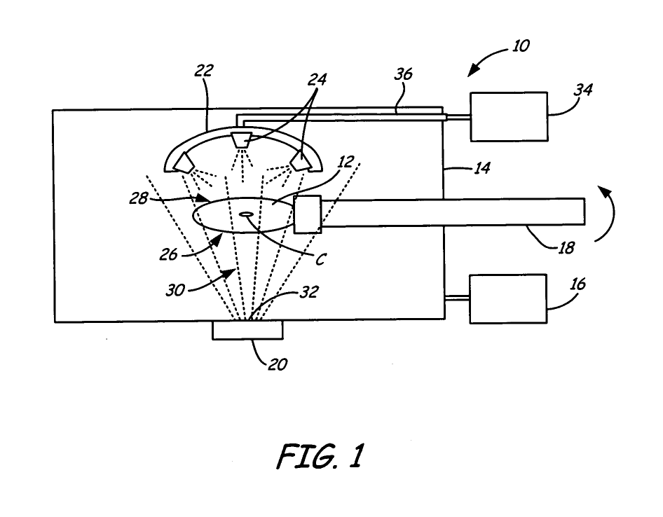

FIG. 1 shows a side view of non-line of sight coating system 10 for coating a part 12. Coating system 10 generally includes housing 14, vacuum pumping system 16, shaft 18, vapor source 20, shield 22, and nozzles 24. Coating system 10 may be retrofitted into current vapor coating processes to apply a thermal barrier coating (TBC) to line of sight regions 26 and non-line of sight regions 28 of part 12. In addition, coating system 10 also accelerates line of sight coating of part 12. Coating part 12 with TBC increases the life of part 12 by preventing failure due to oxidation and thermal mechanical fatigue.

The TBC is applied to part 12 within housing 14, which provides a low pressure environment. Vacuum pumping system 16 is connected to housing 14 and maintains the pressure within housing 14 by continuously pumping air out of housing 14. In an exemplary embodiment, the pressure within housing 14 is maintained below atmospheric pressure. In an exemplary embodiment, the pressure within housing 14 is maintained at between approximately 6×10⁻⁵ millibar and approximately 2×10⁻³ millibar.

As can be seen in FIG. 1, part 12 is positioned in housing 14 by shaft 18. Shaft 18 positions part 12 in housing 14 substantially halfway between vapor source 20 and shield 22. When part 12 is stationary within housing 14, line of sight regions 26 are in direct alignment with vapor source 20 and non-line of sight regions 28 are in direct alignment with shield 22 and nozzles 24. In an exemplary embodiment, shaft 18 is a rotatable shaft that is capable of exposing all sides of part 12 to vapor source 20. In this case, shaft 18 allows part 12 to pivot radially about a center point C of part 12. This allows line of sight regions 26 to be in direct alignment with shield 22 and nozzles 24, and non-line of sight regions 28 to be in direct alignment with vapor source 20.

Vapor source 20 is positioned immediately adjacent to housing 14 and introduces vapor cloud 30 into housing 14 at aperture 32 of housing 14. Vapor cloud 30 includes the TBC to be coated onto part 12. As vapor cloud 30 reaches part 12, the TBC condenses on part 12 and is applied onto line of sight regions 26 of part 12.

Shield 22 is semi-hemispherical in shape and is positioned within housing 14 opposite vapor source 20 to position nozzles 24 relative to part 12. In an exemplary embodiment, shield 22 surrounds part 12 up to about 180 degrees. Shield 22 and nozzles 24 are connected to an inert gas source 34 through piping 36. Nozzles 24 receive inert gas from inert gas source 34 and provide a gas flow into housing 14. Because vacuum pumping system 16 maintains housing 14 at a low pressure, nozzles 24 need to provide the inert gas at a relatively low pressure. In an exemplary embodiment, nozzles 24 introduce inert gas into housing 14 at a rate of between approximately 0.1 liters per minute (Umin) and approximately 10 Umin. The flow of inert gas from nozzles 24 may be adjusted to maintain particle flow from vapor source 20. Although FIG. 1 depicts coating system 10 as including three nozzles 24, coating system 10 may optionally include any number of nozzles, including only one nozzle, depending on the geometry of part 12 and coating requirements. Although inert gas source 34 is discussed as providing inert gas, inert gas source 34 may also provide other gases that may react chemically with the particles of vapor cloud 30, such as oxygen.

The inert gas from nozzles 24 function to push vapor cloud 30 back toward part 12. As the inert gas from nozzles 24 meets vapor cloud 30, the inert gas causes particle-to-particle interactions and increases randomization within vapor cloud 30. The random collisions allow the particles to have different trajectories toward part 12 and specifically, to non-line of sight regions 28. By creating a randomized vapor cloud, coating system 10 coats non-line of sight regions 28 of part 12, accelerates coating line of sight regions 26 of part 12, and improves the microstructure in regions of part 12 that are slightly off angle to vapor source 20. In an exemplary embodiment, part 12 is completely coated after being positioned in housing 14 for between approximately b 20 minutes and approximately 120 minutes.

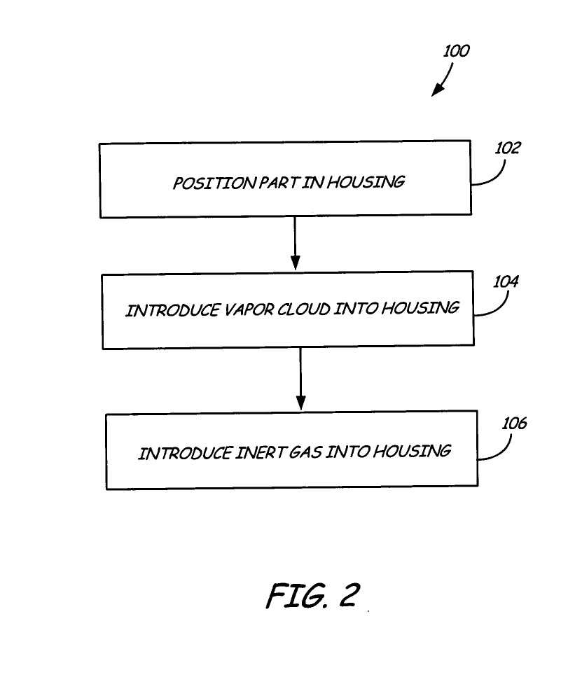

FIG. 2 shows a block diagram of an exemplary, non-limiting method 100 of coating non-line of sight regions 28 of part 12. Conventional coating techniques typically only coat line of sight regions 26 of part 12. Method 100 allows coating non-line of sight regions 28 as well as line of sight regions 26 of part 12. As shown in Box 102, part 12 is first positioned in housing 14 between vapor source 20 and shield 22 with nozzles 24. Vapor cloud 30 is introduced into housing 14 by vapor source 20, coating line of sight regions 26 of part 12, as shown in Box 104. As vapor cloud 30 is being introduced into housing 14, nozzles 24 provide a gas flow of inert gas from inert gas source 34 to interact with vapor cloud 30, Box 106. As the inert gas interacts with vapor cloud 30, the particle-to-particle interactions create a randomized cloud. The randomized cloud pushes back toward part 12 and coats non-line of sight regions 28. During this process, the coating of line of sight regions 26 is also accelerated, and the microstructure in areas of part 12 that were slightly off angle to vapor source 20 are also improved.

Although the present invention has been described with reference to preferred embodiments, workers skilled in the art will recognize that changes may be made in form and detail without departing from the spirit and scope of the invention.

1. An apparatus for non-line of sight coating of a part, the apparatus comprising:
a housing;
a vapor source for producing a vapor cloud into the housing toward the part;
at least one nozzle positioned for providing a gas flow to interact with the vapor cloud; and
a vacuum pumping system for maintaining a pressure within the housing.

2. The apparatus of claim 1, and further comprising a shaft for positioning the part within the housing between the vapor source and the nozzle.

3. The apparatus of claim 2, wherein the shaft is a rotatable shaft.

4. The apparatus of claim 1, and further comprising a shield positioned within the housing opposite the vapor source.

5. The apparatus of claim 4, wherein the shield is semi-hemispherical.

6. The apparatus of claim 1, and further comprising a plurality of nozzles.

7. The apparatus of claim 1, wherein the nozzle provides a gas flow selected from the group consisting of: an inert gas and oxygen.

8. The apparatus of claim 1, wherein the nozzle is positioned to provide a gas flow to interact with the vapor cloud to create a randomized cloud.

9. A system for coating non-line of sight regions of a device, the system comprising:
a housing;
a vapor source positioned to produce a vapor cloud within the housing;
a nozzle positioned opposite the non-line of sight regions of the device for providing a gas flow toward the vapor cloud; and
a pumping system for maintaining the housing within a pressure range.

10. The system of claim 9, and further comprising shaft for positioning the device within the housing.

11. The system of claim 9, and further comprising a shield positioned in the housing opposite the vapor source and proximate the nozzle.

12. The system of claim 9, wherein the nozzle is positioned to provide a gas flow to interact with the vapor cloud to create a randomized cloud.

13. The system of claim 12, wherein gas flow from the nozzle is selected from the group consisting of: an inert gas and oxygen.

14. The system of claim 9, and further comprising a plurality of nozzles.

15. A method of coating non-line of sight regions of a part, the method comprising:
positioning the part within an enclosed housing;
producing a vapor cloud into the housing toward the part;
providing a gas flow into the housing toward the non-line of sight regions of the part, wherein the gas flow interacts with the vapor cloud; and
maintaining the enclosed housing within a predetermined pressure range.

16. The method of claim 15, wherein positioning the part within an enclosed housing comprising using a shaft.

17. The method of claim 15, wherein producing a vapor cloud into the housing comprises using a vapor source.

18. The method of claim 15, wherein providing a gas flow into the housing comprises using at least one nozzle.

19. The method of claim 15, wherein the gas flow interacts with the vapor cloud to create a randomized cloud.

20. The method of claim 15, wherein the predetermined pressure range is less than atmospheric pressure.
